(19) United States
(12) Patent Application Publication
(10) Pub. No.: US 2026/0323846 A1
(43) Pub. Date: Oct. 15, 2026

(54) HOUSING ASSEMBLY FOR ELECTRONIC DEVICE

(71) Applicant: Conner Gibson, Lethbridge (CA)

(72) Inventor: Conner Gibson, Lethbridge (CA)

(21) Appl. No.: 19/179,474

(22) Filed: Apr. 15, 2025

(51) Int. Cl. H05K 5/00; G01S 1/04; H04N 21/422; H05K 5/02; H05K 5/03

(52) U.S. Cl. CPC H05K 5/0086; G01S 1/0426; H05K 5/0247; H05K 5/03; H04N 21/42206

(57) ABSTRACT

A secure, protective enclosure system for remote controls is disclosed, designed to prevent damage, loss, and unauthorized access to battery compartments. The enclosure, configured to receive a variety of remote control shapes and sizes, includes a locking mechanism that requires a tool to access the enclosed device, thereby improving safety and control. The system permits full functionality of the remote control via access ports or flexible interfaces while it remains housed. The enclosure may further include shock-absorbing materials, ergonomic enhancements, and mounting or portability features. Optional features include integrated holders for tracking devices and high-visibility or disinfectable finishes, making the product suitable for use in domestic, commercial, educational, or healthcare environments.

### CROSS REFERENCE TO RELATED APPLICATIONS

The present application claims priority to U.S. Provisional Application No. 63/634,803, entitled “UNIVERSAL REMOTE CADDY AND MIXING JAR LID” filed on Apr. 16, 2024, the content of which is incorporated herein by reference in their entirety.

### FIELD

The present disclosure relates generally to protective accessories for electronic devices, and more particularly to enclosures for remote control units. Specifically, the present disclosure provides a lockable, impact-resistant housing designed to accommodate a wide variety of remote controls, enhance their durability, and restrict unauthorized or unsafe access to internal compartments, while maintaining full operational usability.

### BACKGROUND

Remote controls are ubiquitous in modern households and commercial spaces, serving as primary input devices for televisions, streaming devices, air conditioners, and other electronics. Despite their utility, remote controls are prone to several persistent problems, including frequent misplacement, breakage from drops, battery theft or ingestion hazards, and misuse by unauthorized users such as children or pets. Additionally, conventional remote controls lack features that support visibility, hygiene, or ease of handling for users with reduced dexterity.

Existing solutions, such as universal remotes or smartphone apps, offer limited improvements and fail to address the underlying physical vulnerabilities and safety concerns. Enclosures, if available at all, are either device-specific, fail to lock securely, or obstruct user interaction with the remote's features.

There is therefore a need for a universal, secure, and user-friendly enclosure system that can protect a remote control from damage, prevent access to its battery compartment, and improve usability in both household and institutional settings.

### SUMMARY

In an aspect, the present disclosure provides a housing assembly for protecting an electronic device, the housing assembly comprising: a housing comprising a housing cavity to accommodate the electronic device; a cover releasably secured to the housing to enclose the electronic device within the housing assembly; at least one access window positioned on at least one of the housing and the cover to allow a user to access the electronic device enclosed within the housing assembly; and, at least one securement fastener to releasably secure the cover to the housing.

The present disclosure also provides a housing assembly, which is an enclosure system designed to secure and protect remote control devices while preserving their full functionality. The housing assembly is constructed of high-impact resistant materials and is available in multiple structural configurations, including two-piece housings, insert-based modules, and single-piece shells with locking mechanisms. Each configuration includes access openings or flexible membranes that align with the buttons and features of the enclosed remote, allowing uninterrupted operation.

A feature of the disclosure is its tool-operated locking mechanism, which ensures the remote remains securely housed and inaccessible to children, unauthorized users, or environmental factors. Locking mechanisms may include screws, latches, or pins, depending on the embodiment.

In some embodiments, the housing includes additional components such as a pocket for a Bluetooth or Tile™-style tracker, ergonomic features for enhanced grip, and materials suitable for visual contrast or antimicrobial cleaning. Mounting options allow the unit to be affixed to surfaces such as tables, walls, or bedsides, or carried as a portable item.

The housing is adaptable to a wide range of remote control models and is particularly suited for use in homes with young children or pets, as well as in hospitals, hotels, classrooms, and other environments where security, hygiene, or durability are critical.

This disclosure provides a family of protective and functional enclosures designed for use with hand-held electronic devices and tools, including remote controls, writing instruments, and food mixing implements. Each embodiment addresses a specific need relating to physical protection, tamper resistance, user accessibility, or containment of materials during operation.

In one aspect, the disclosure provides a multi-part protective housing for a remote control, comprising a base and a cover secured using tool-operated fasteners to deter tampering. The housing may include windows or ports to allow continued access to infrared transmitters, buttons, volume controls, and other device functions. In some embodiments, a locating tag pocket is included to accept tracking devices such as Apple AirTags™ or Tiles™, enabling the user to locate the device if misplaced.

In another aspect, a single-fastener housing is provided, incorporating an alignment lip and lip receptacle that function as a secondary interlocking system. This reduces manufacturing complexity while preserving durability and alignment, forming a secure enclosure with fewer components.

A further embodiment includes a shock-absorbing outer sleeve designed to surround and protect the remote housing. The sleeve is made of elastomeric material and includes hollow internal wall structures filled with air, which collapse and deform on impact to absorb and dissipate energy. Molded lugs integrated into the sleeve engage corresponding receptacles in the housing to form a unified system while avoiding rigid stress points. Tamper-resistant fasteners may be used to secure the sleeve to the housing.

Another embodiment provides a button-cover flap, which overlays specific sections of the remote control to prevent accidental or unauthorized button activation. A deliberate gap between the flap and the underlying buttons ensures that pressure on the flap will not actuate the covered controls.

In an adjustable version, the disclosure provides a remote housing with adjustable internal length and width, using tool-operated screws to reposition sliding plates. This allows a single enclosure design to accommodate a variety of remote control dimensions. Variations in thickness may be addressed using the cover securement fasteners, which draw the back plate to the main housing at variable depths.

The disclosure also includes a tamper-resistant pen protector in which a pen is inserted into a rigid housing and secured in place by a fastener whose end physically prevents the pen's removal. A respiratory port, extending longitudinally through the housing, permits airflow in the event the device is inserted into a user's mouth, reducing the risk of suffocation.

The disclosure also provides a mixing lid for containers, allowing users to re-integrate separated food phases (e.g., oils and solids in nut butters) using common kitchen mixers without transferring contents to another vessel. The lid includes an adaptable seal around its edge to accommodate various container mouths, and an optional slot-shaped mixing aperture with a flexible silicone spatter guard that limits mess while allowing mixing tools to pass through. This embodiment improves cleanliness and convenience during food preparation and is compatible with standard household mixers.

Together, these embodiments provide a comprehensive set of durable, tamper-resistant, safety-enhancing, and user-friendly solutions that extend across multiple consumer applications.

### BRIEF DESCRIPTION OF THE DRAWINGS

FIG. 1A is a top down perspective view of a protective housing assembly for a remote control, showing the cover secured to the housing with multiple fasteners and various access windows.

FIG. 1B is a sectional perspective view of the housing assembly shown in FIG. 1A, illustrating the internal arrangement and a dedicated pocket for receiving a tracking device such as an AirTag™ or Tile™.

FIG. 1C is an exploded perspective view of the housing assembly of FIG. 1A, showing the relationship between the housing, cover, internal device, tracking tag, and multiple fasteners.

FIG. 2A is an isometric view of a single-fastener protective housing assembly for a remote control, showing the main housing and back cover in an assembled configuration.

FIG. 2B is a sectional view of the single-fastener housing assembly shown in FIG. 2A, illustrating the internal relationship between the main housing, the electronic device, and the back cover.

FIG. 2C is an exploded perspective view of the single-fastener housing of FIG. 2A, showing the assembly order of components including the alignment lip, lip receptacle, and the single securement fastener.

FIG. 3A is a top isometric view of an impact-absorbing sleeve configured to surround and protect a remote control housing, illustrating the outer form of the shock-absorbing structure and access windows aligned with device functions.

FIG. 3B is a bottom isometric view of the impact-absorbing sleeve, showing the underside access ports including those for headphone, volume, and infrared functionality.

FIG. 3C is a center cross-sectional view of the impact-absorbing sleeve, illustrating the internal cavity designed to receive the remote housing and the surrounding hollow regions that enhance energy absorption.

FIG. 3D is an offset cross-sectional view of the impact-absorbing sleeve and the internal remote control housing, specifically showing the securement of the two components using tool-operated fasteners positioned through molded lugs and corresponding receptacles.

FIG. 3E is an isometric exploded front view of the impact-absorbing sleeve and internal remote housing, showing the layered assembly, fasteners, and shock-absorbing components prior to installation.

FIG. 3F is a rear exploded view of the sleeve and remote housing system, illustrating the alignment of ports and access features, and the positioning of the shock-absorbing sleeve relative to the enclosed remote housing.

FIG. 4A is an isometric view of a remote control housing featuring an extended button-covering flap, which is designed to overlay and obscure specific control buttons, such as quick-launch or settings buttons, while maintaining access to other functions.

FIG. 4B is a cross-sectional view of the housing and button cover assembly shown in FIG. 4A, illustrating a defined gap between the flap and the underlying hidden buttons, preventing the flap from activating buttons when pressure is applied externally.

FIG. 5A is an isometric view of a remote control housing featuring adjustable-fit functionality, designed to accommodate a range of remote control sizes through internal length and width adjustment mechanisms.

FIG. 5B is a side cross-sectional view of the adjustable-fit housing, illustrating an oversized internal gap between the remote control and the housing walls due to a length mismatch prior to adjustment.

FIG. 5C is a side cross-sectional view of the same housing as in FIG. 5B, showing the improved fit after adjustment, where the lengthwise gap between the remote and the internal wall of the housing has been substantially reduced or eliminated.

FIG. 5D is a cross-sectional view of the adjustable housing showing an excessive lateral gap between the sides of the remote control and the interior sidewalls of the housing prior to width adjustment.

FIG. 5E is a cross-sectional view of the same system as in FIG. 5D, showing the result after width adjustment, with the lateral spacing minimized to securely fit the remote control. Width and length adjustments are achieved via tool-operated screws, although alternative adjustment methods may be implemented by one skilled in the art.

FIG. 6A is an isometric view of a pen enclosure system designed to secure a writing instrument within a protective housing, illustrating the assembled configuration with openings for the pen tip and integrated respiratory ports for airflow.

FIG. 6B is an exploded isometric view of the pen enclosure, showing the insertion path of the pen into the housing and the arrangement of the respiratory ports, and locking fastener.

FIG. 6C is a side cross-sectional view of the pen enclosure system in an assembled state, showing the internal positioning of the pen within the housing, the alignment of the pen tip with the tip-protrusion opening, and the tool-operated fastener. The distal end of the fastener projects into the pen cavity, thereby physically retaining the pen in position and preventing its removal unless the fastener is withdrawn.

FIG. 6D is a cross-sectional view of the pen protector, illustrating a continuous internal respiratory port that extends longitudinally along the length of the housing. This channel permits airflow through the enclosure from end to end, enabling the user to breathe through the pen housing in the event it is accidentally inserted into the mouth.

FIG. 7A is an isometric view of a mixing lid system mounted on a container, illustrating the lid with an opening configured to receive a powered mixing implement such as a handheld electric mixer.

FIG. 7B is a cross-sectional view of the mixing system shown in FIG. 7A, illustrating the mixing implement inserted through the lid opening and into the contents of the container. The figure also shows the placement of the optional flexible guard positioned over the lid opening to reduce spatter during operation.

FIG. 7C is an exploded isometric view of the mixing lid system, showing the lid, container, and flexible guard as separate components. The flexible guard is configured to deform around the mixing implement while preventing the escape of material from the container during mixing.

### DETAILED DESCRIPTION

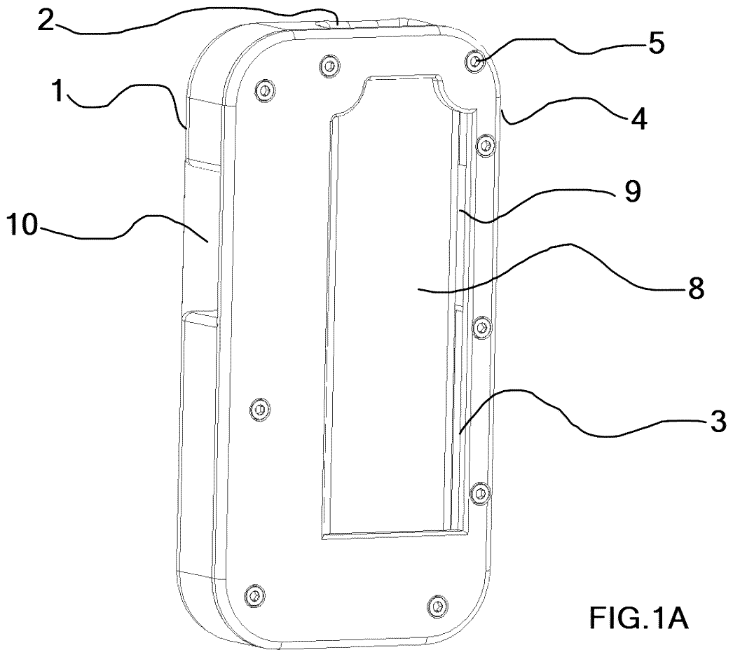

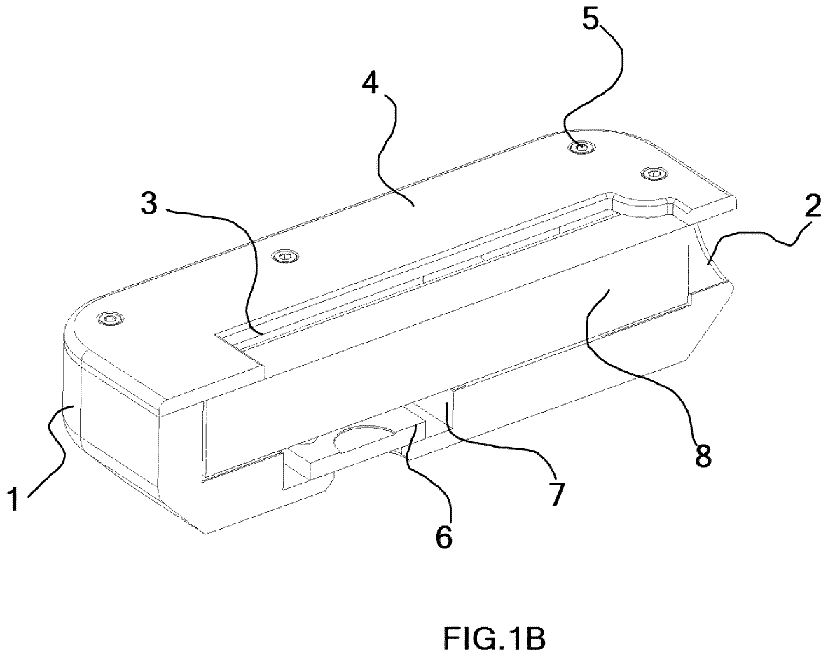

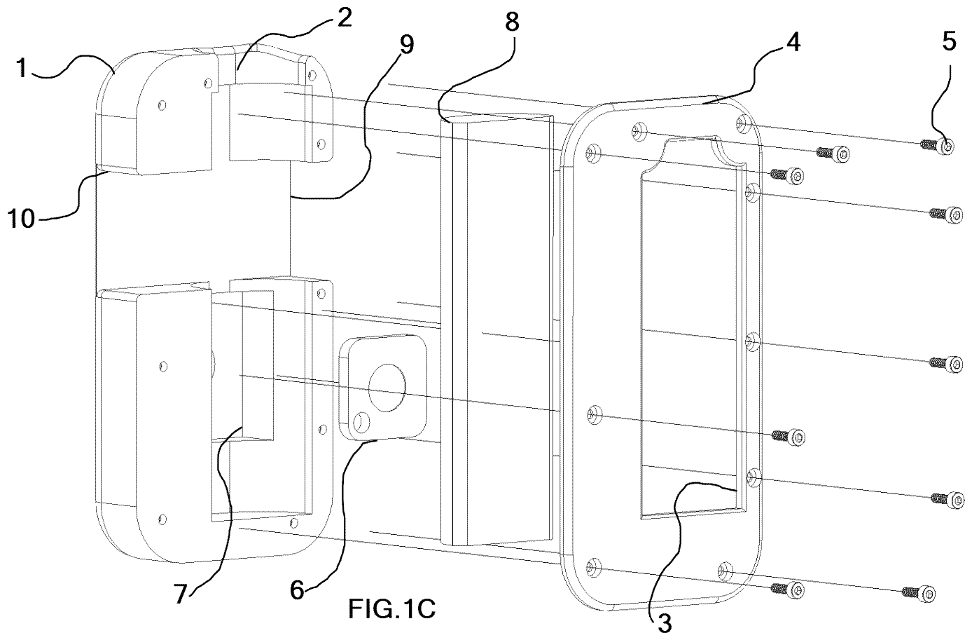

With reference to FIGS. 1A through 1C, and according to a first embodiment of the present disclosure, a protective remote control enclosure system generally described as a multi-fastener housing assembly is shown. This embodiment is designed to securely encase a standard electronic remote control device (8) within a protective housing (1), providing physical durability and preventing unauthorized access to the internal components, including the battery compartment.

The housing assembly includes a lower protective housing (1) and an upper cover (4), which together enclose the electronic device (8). The cover (4) is secured to the housing (1) by a plurality r securement fasteners (5), positioned at distributed locations around the perimeter of the assembly. These fasteners may include screws, pins, or other tool-operated fasteners, and are intended to require a specific tool for removal to inhibit tampering or unintended disassembly.

The assembled housing includes a number of strategically positioned access features to enable full functional use of the enclosed remote control without removing it from the enclosure. These include: an IR access port (2) for transmission of infrared signals, a button access window (3) aligned with the device's primary user interface, a volume access window (9), and a headphone access window (10), if applicable to the enclosed device.

These ports may be implemented as open cutouts or covered by flexible membranes that permit interaction while maintaining a degree of environmental protection.

An optional locating tag pocket (7) is integrated into the interior surface of the housing or cover and is configured to receive a locating tag (6), such as an Apple™ AirTag™, Tile™, or similar Bluetooth- or RFID-based tracking device. The locating tag enables the entire assembly to be found via digital means in the event of misplacement. The pocket may be recessed and friction-fit, or include a retaining feature to hold the tag in place during handling or use.

FIG. 1A illustrates the fully assembled state of the enclosure. FIG. 1B provides a sectional view highlighting the internal relationship between the housing, cover, electronic device, and locating tag. FIG. 1C presents an exploded view of the assembly, showing the housing (1), cover (4), fasteners (5), locating tag (6), locating tag pocket (7), and the enclosed electronic device (8) in their relative positions prior to assembly.

This embodiment is particularly well-suited for high-abuse environments such as hospitals, schools, or homes with children or pets, where protection from physical damage and loss is a priority. While this embodiment uses multiple fasteners for high security and durability, alternative configurations with fewer fasteners or different locking mechanisms are described in subsequent embodiments.

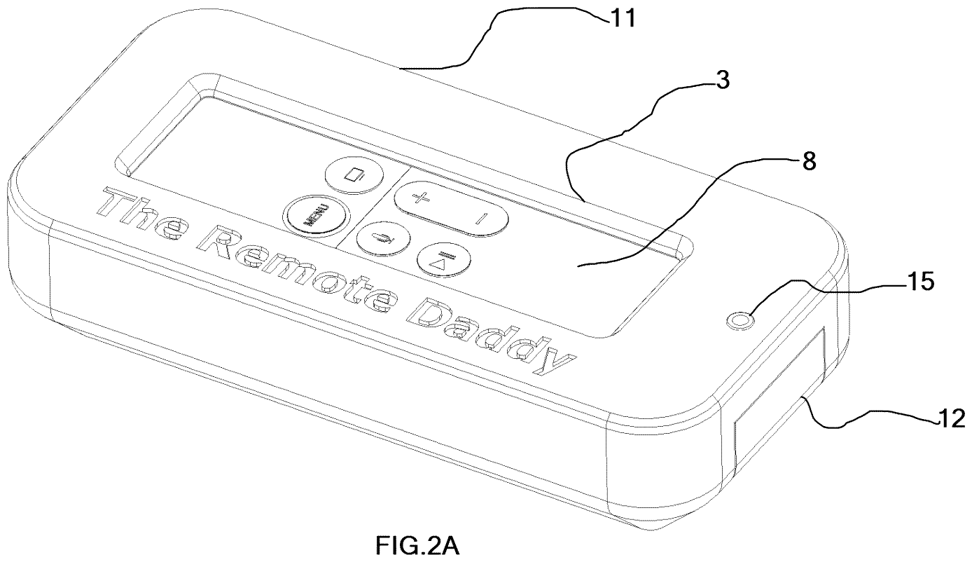

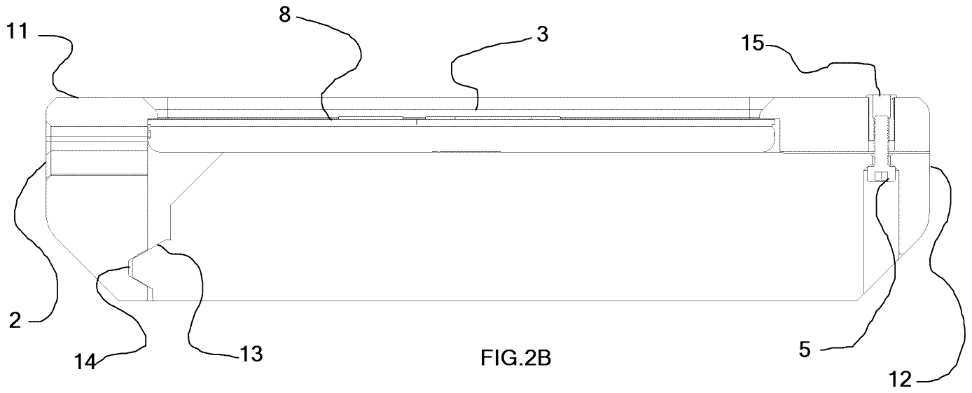

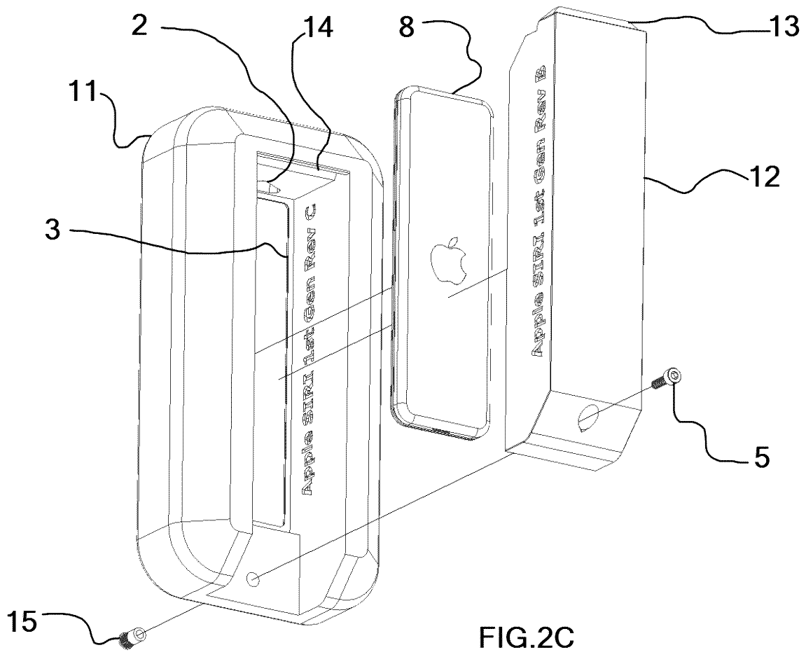

With reference to FIGS. 2A through 2C, and according to a second preferred embodiment of the present disclosure, a protective remote control enclosure system is illustrated and described. This embodiment utilizes a simplified, streamlined structure that enables quick and secure assembly via a single tool-operated fastener, while preserving the tamper-resistant, impact-protective, and functionally accessible features of the multi-fastener design.

The enclosure comprises a main protective housing (11) and a locking back cover (12), which together define a cavity for receiving and retaining an electronic device, such as a remote control. The housing (11) and cover (12) are mechanically aligned and interlocked using an alignment lip (13) formed along the edge of one component, and a corresponding lip receptacle (14) formed in the mating component.

These features function not only to align the two components during assembly, but also to mechanically interlock the main housing (11) and the locking back cover (12). The alignment lip (13) engages with the corresponding lip receptacle (14) to create a physical interference fit or structural engagement that resists separation of the two parts. Together with the tool-operated fastener, this interlocking feature forms a dual-retention system that maintains the structural integrity of the enclosure even under stress or impact. Without this engagement, the housing could separate despite the presence of the fastener.

To secure the housing, a single fastener is inserted through an opening in the back cover (12) and threaded into a female threaded insert (15) embedded in the main housing (11). This fastener is configured to require a tool for insertion and removal, thereby providing tamper resistance and discouraging unauthorized disassembly. The use of a single fastener reduces manufacturing complexity and user effort while still achieving a secure closure.

FIG. 2A presents an isometric view of the fully assembled housing, showing the overall form and closure. FIG. 2B is a sectional view illustrating the internal engagement between the housing (11), the cover (12), and the lip-receptacle interface (13, 14), as well as the placement of the fastener. FIG. 2C is an exploded view detailing the components prior to assembly, including the alignment lip, lip receptacle, and central fastener.

This embodiment retains the same external access features described in the first embodiment, such as windows or ports for infrared transmission, button control, volume, and headphone access (not separately labeled in this figure set for clarity). Optional internal features, such as a locating tag pocket and tracking tag, may also be integrated into the housing as described in prior embodiments.

The single-fastener embodiment is especially well-suited for environments where simplified assembly and reduced part count are desirable, such as large-scale deployments in schools, clinics, or commercial installations. Its clean design, reduced tool requirements, and ease of access for authorized personnel make it the inventor's preferred configuration.

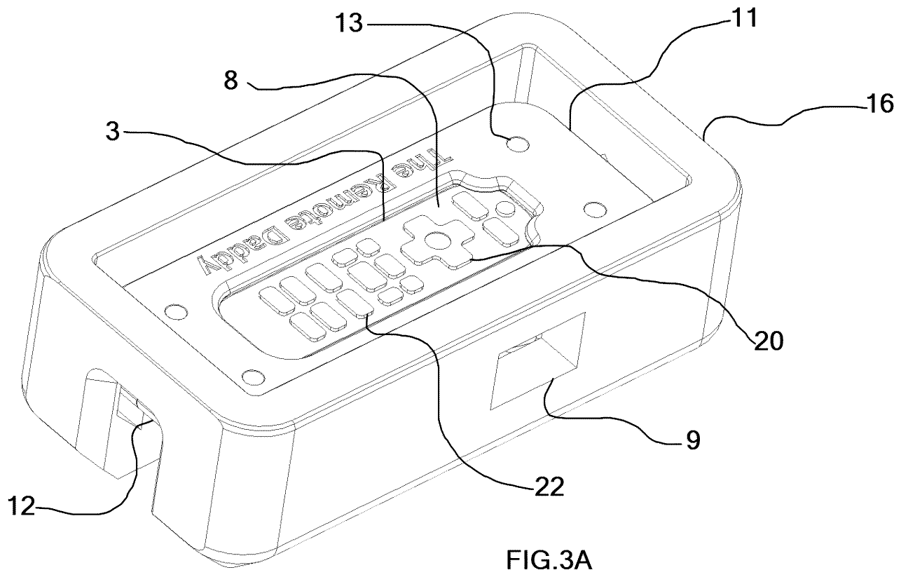

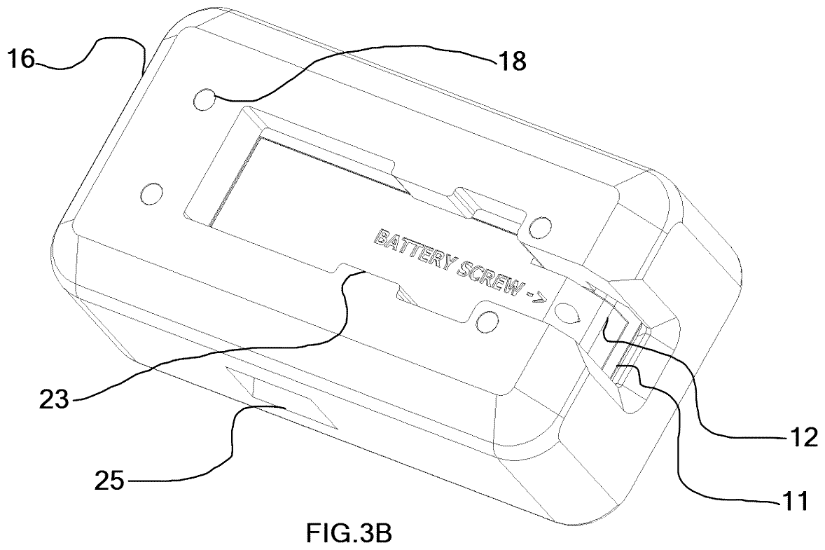

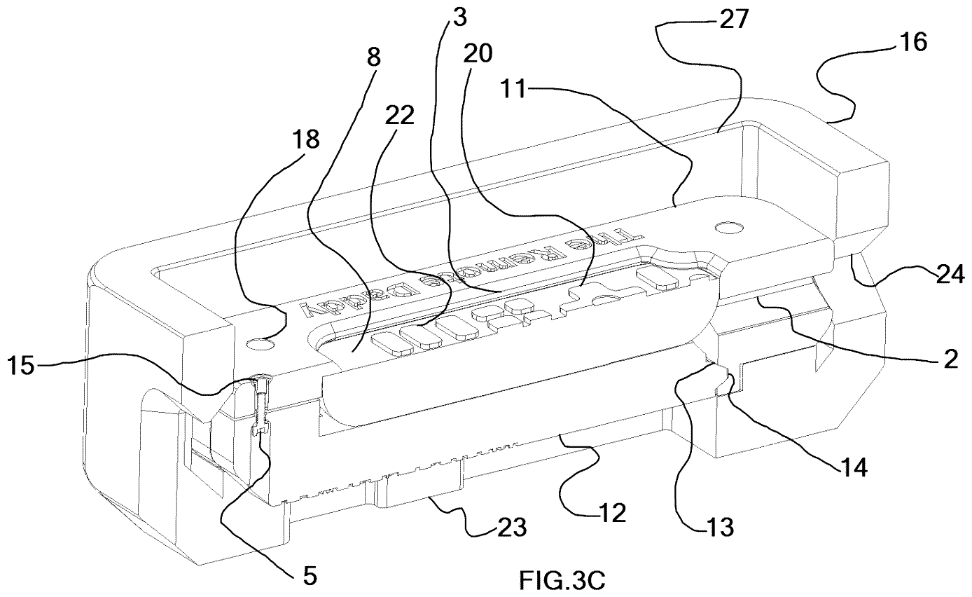

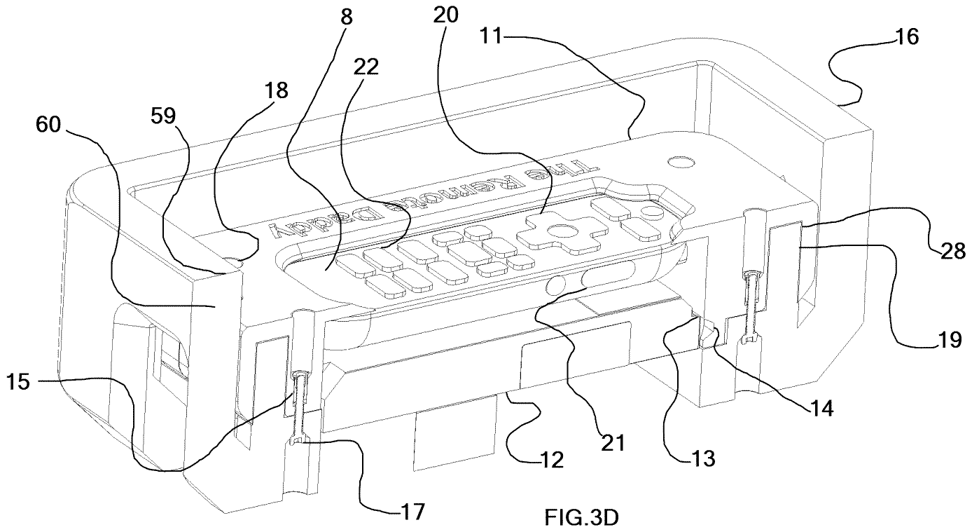

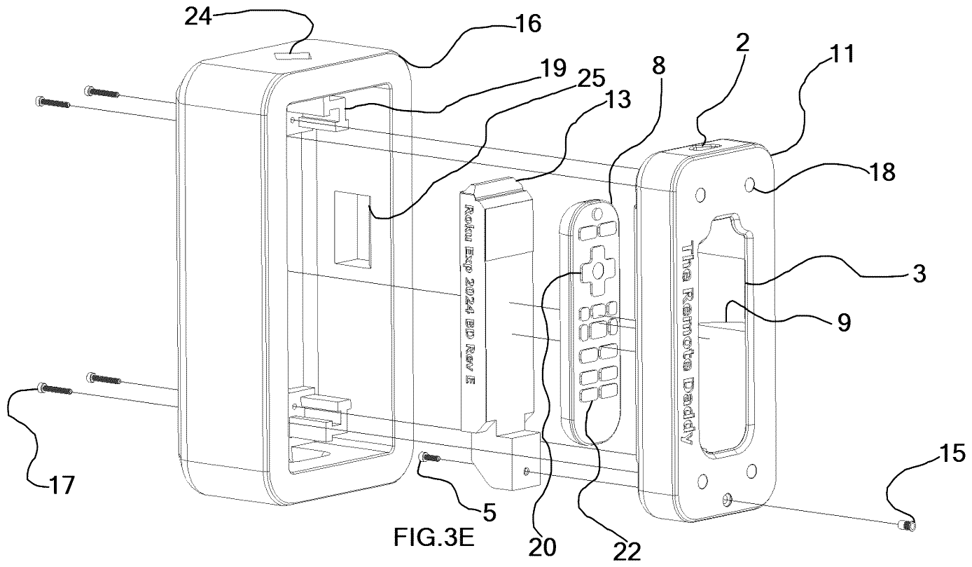

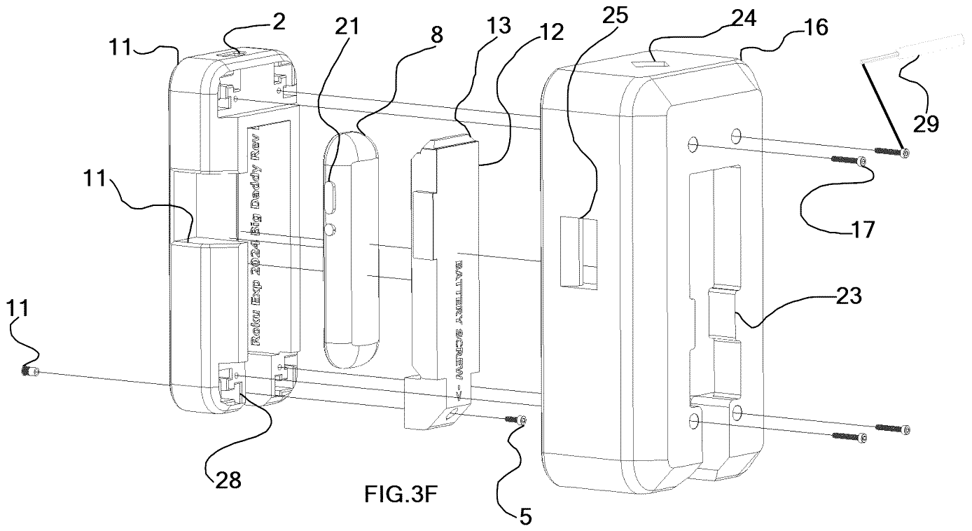

With reference now to FIGS. 3A through 3F, and according to a third embodiment of the present disclosure, a shock-absorbing outer sleeve, configured to receive and protect the remote control housing described in the first and second embodiments is shown. The sleeve serves as a secondary enclosure, providing substantial impact resistance through both its material properties and its unique hollow-wall construction.

The outer sleeve comprises a deformable, elastomeric body (16), preferably molded from rubber, silicone, or a similar energy-absorbing material. The sleeve is form-shaped to accept the remote housing in its central cavity, with an internal geometry that matches the contour of the enclosure to ensure a snug fit. However, the key structural feature of this embodiment is that the walls of the sleeve themselves are hollow-incorporating air channels or chambers throughout their thickness.

Rather than being solid, the approximately 1-inch-thick sleeve includes thin structural walls (59) (e.g., 1 mm thick) surrounding internal air voids (60). These voids allow the sleeve to collapse and deform under impact, thereby slowing the transfer of kinetic energy and reducing peak force transmission to the enclosed remote control housing. This structural damping is based on physical principles of momentum conservation and impact absorption—by extending the impact time, the sleeve reduces the damaging impulse delivered to the interior device.

The outer sleeve includes a series of functional openings to permit continued use of the remote control while enclosed, such as: shock-IR port (24), shock-volume port (25), and shock-button access window (27).

To retain the remote housing within the sleeve, the system uses molded lugs (19) which mate with the female-lug-receptacle (28) and shock-absorbing surround securement fasteners (17), inserted through corresponding access ports (18), as shown in FIGS. 3D through 3F. The fasteners are tool-operated and provide a tamper-resistant locking mechanism, preventing unauthorized removal of the sleeve.

The molded lugs and receptacles, however, serve a distinct and critical structural function. They are integrated with the flexible hollow-wall structure of the sleeve and are designed to mechanically interlock the sleeve and housing as a unified, impact-resistant assembly. The lugs are deformable and engage internal receptacles in a manner that enables flexibility and energy distribution during impact. This configuration allows the sleeve to spread out mechanical forces across a broader surface area, avoiding the creation of hard points that would otherwise concentrate stress and reduce the effectiveness of the cushioning. Together with the hollow internal wall structure, the lugs ensure that the sleeve and housing function as a single energy-dampening system without compromising the protective integrity.

FIG. 3A shows a top isometric view of the sleeve, FIG. 3B is a bottom isometric view showing port access, FIG. 3C provides a center cross-sectional view revealing the air-filled wall construction and the housing-receiving cavity, FIG. 3D is an offset cross-sectional view illustrating how the internal housing is secured to the sleeve via fasteners and integrated lugs, FIG. 3E is an isometric exploded front view showing how the sleeve and housing align and assemble, FIG. 3F is a rear exploded view, illustrating the opposite end of the assembly.

This embodiment is particularly useful in environments where the remote control assembly or other enclosed devices may be subjected to frequent handling, dropping, or abuse-such as in pediatric care, settings, institutional high-traffic public environments, or homes of individuals with disabilities or behavioral conditions where devices may be intentionally or unintentionally damaged. The shock-absorbing sleeve offers a modular, adaptable protective solution, allowing it to be optionally installed over any compatible enclosure, including those described in the first and second embodiments (remote housing). Its form-fitting, energy-dampening structure provides a versatile solution for enhancing device durability across a variety of use cases.

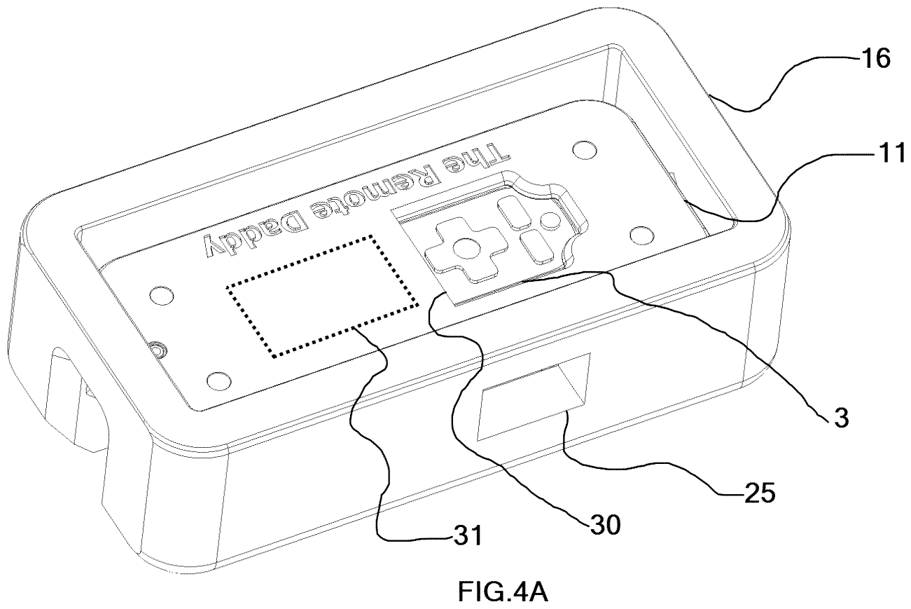

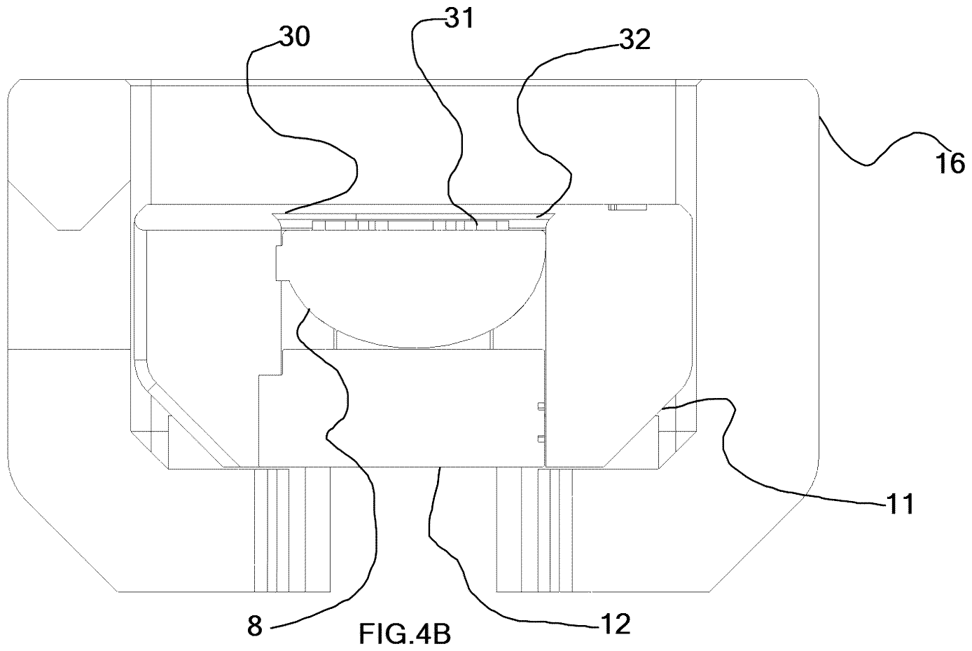

With reference to FIGS. 4A and 4B, and according to a fourth embodiment of the present disclosure, a button-covering flap integrated into or attached to the remote control housing is shown. The purpose of the flap is to physically obstruct access to specific buttons—such as quick-launch, settings, or parental control override buttons—that the user may wish to restrict without locking down the entire device.

The button-cover flap (30) is an extended portion of the housing that overlays one or more designated control surfaces on the remote. The flap may be integral to the housing body or separately attached using adhesive, fasteners, or a living hinge. The flap is positioned to lie directly above a section of the remote's button surface, referred to as the hidden buttons (31), while leaving the rest of the control area fully accessible through the standard button access window (3).

A key feature of this embodiment is the inclusion of a button cover gap (32), as shown in the cross-sectional view in FIG. 4B. This gap (32) is intentionally designed between the underside of the flap (30) and the top surface of the hidden buttons (31), preventing the flap (30) from accidentally pressing or actuating the covered buttons if external force is applied. This ensures that the flap (30) serves only as a mechanical barrier, not as a secondary button actuator.

FIG. 4A shows an isometric view of the housing with the flap (30) in place, visually concealing the designated buttons.

FIG. 4B is a cross-sectional view illustrating the air gap (32) between the flap (30) and the underlying button array (31).

The button-cover flap (30) may be rigid or flexible, opaque or transparent, and removable or permanent, depending on use-case requirements. In some embodiments, the flap (30) may be secured with tool-operated fasteners or locking tabs, enabling it to be deployed only by authorized users. This configuration is ideal for applications involving young children, cognitively impaired individuals, or institutional settings where accidental or inappropriate activation of specific functions must be avoided without limiting the general usability of the remote.

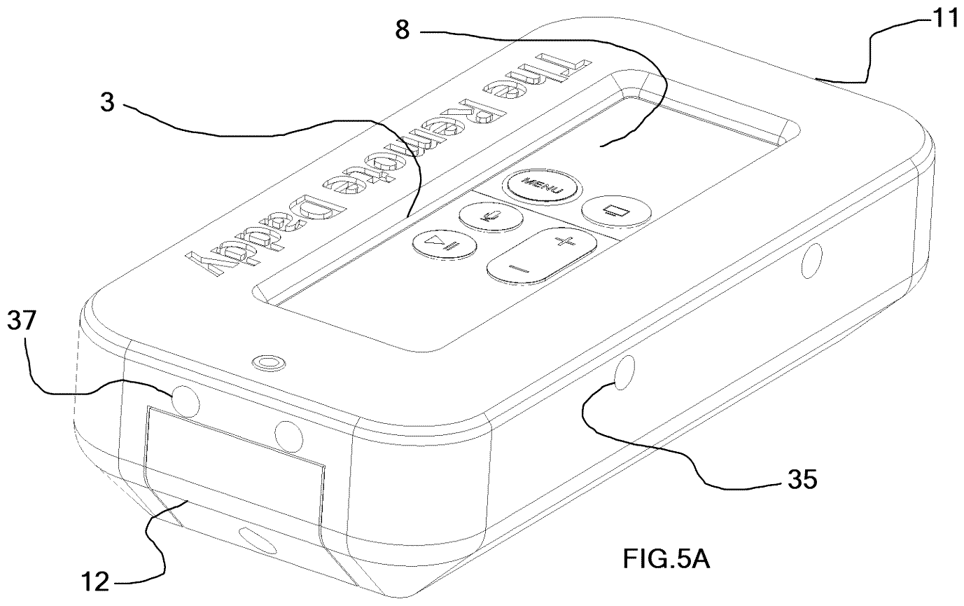

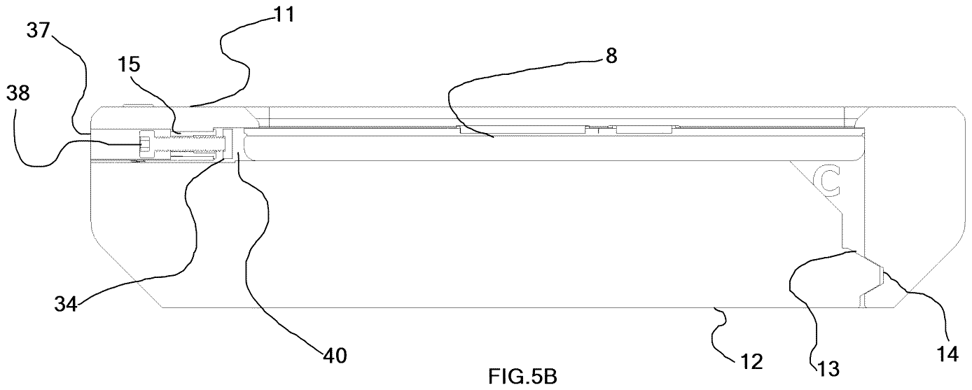

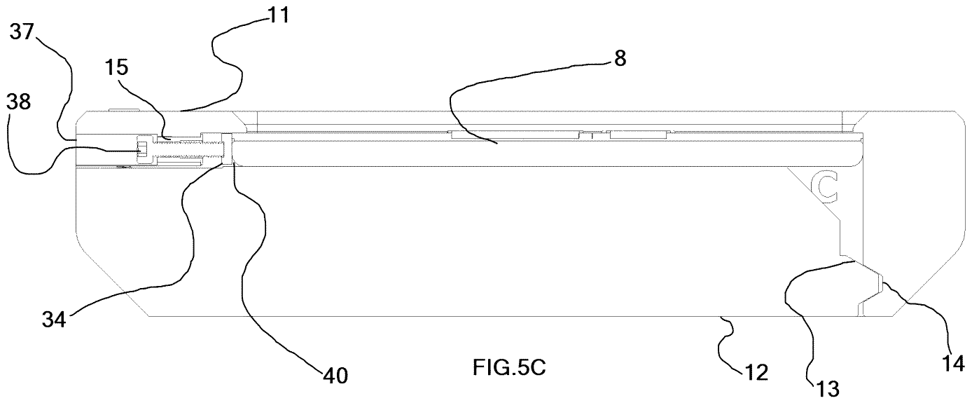

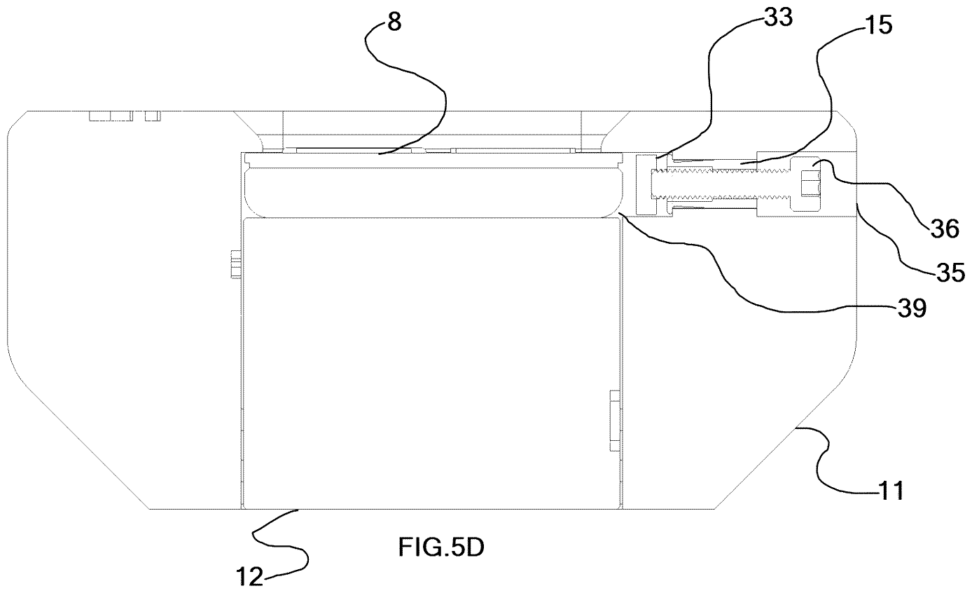

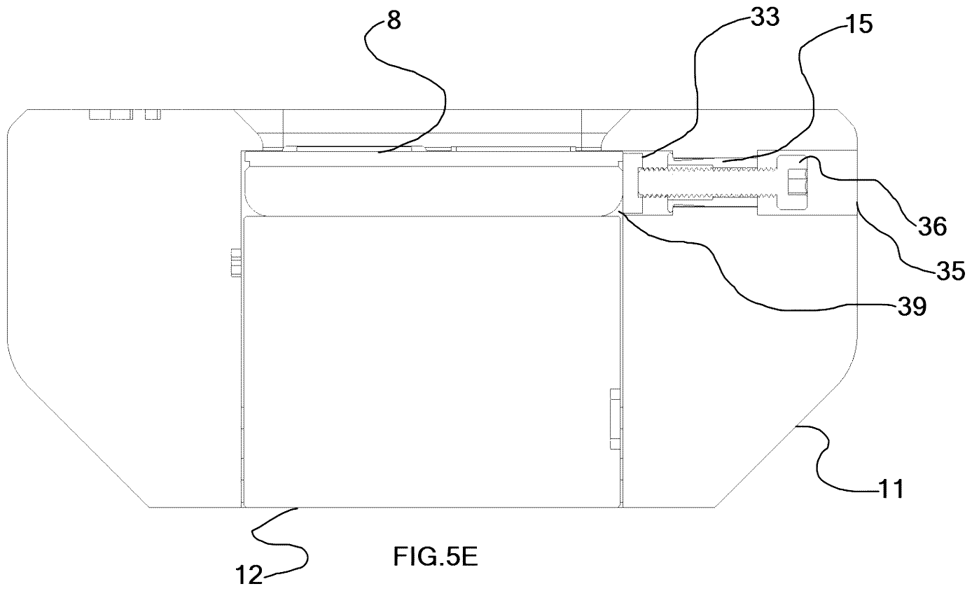

Referring now to FIGS. 5A through 5E, and according to a fifth embodiment of the present disclosure, an adjustable-fit protective housing is shown. The adjustable-fit protective housing enables a single enclosure to accommodate a variety of remote control sizes by modifying both its internal length and width. This is particularly useful in commercial or institutional applications where remote models may vary, but standard protection and security are required.

The housing includes a main body with one or more sliding plate assemblies that are adjustable in relation to the main housing frame. These plate assemblies may be configured to extend or contract the internal dimensions of the enclosure, both longitudinally and laterally, depending on the size of the enclosed device. Lengthwise adjustment is illustrated in FIGS. 5B and 5C, FIG. 5B shows a side cross-sectional view where the internal remote is significantly shorter than the enclosure, creating a gap due to an unadjusted length, FIG. 5C shows the same view after the length has been adjusted to bring the plate into contact with the end of the remote, eliminating the gap and securing the fit, widthwise adjustment is shown in FIGS. 5D and 5E. FIG. 5D is a top cross-sectional view showing excessive lateral space between the sides of the remote and the housing walls. FIG. 5E shows the result of width adjustment, where the side plates have been brought inward to securely hold the remote in position.

The adjustments are achieved using tool-operated fasteners, such as set screws or bolts, accessed through designated adjustment screw locations (35 & 37) shown in the figures. The screws permit controlled movement of the adjustable plates and then lock them into place to prevent shifting during use. Although this embodiment is shown with tool-operated adjustments for tamper resistance and precision, alternate implementations using sliders, clips, or tool-free mechanisms may also be realized by one skilled in the art. FIG. 5A provides an isometric view of the assembled adjustable housing. FIGS. 5B and 5C demonstrate the before-and-after result of length adjustment. FIGS. 5D and 5E show the same before-and-after progression for width adjustment.

This embodiment is particularly suited for situations where uniform enclosures are needed across a range of remote control models. It offers a flexible platform for manufacturing, installation, and reuse, while maintaining all the protective and tamper-resistant features of the other embodiments.

While the illustrated implementation allows for explicit adjustment in both length and width, the system can also be adapted to accommodate variations in remote control thickness. In the housing configurations described in the first a and second embodiments, cover securement fasteners are used to draw the back cover tightly against the main housing. This allows for passive depth adjustment by flexibly conforming the enclosure to the thickness of the enclosed remote. Thus, the design supports full three-dimensional adaptability without requiring a separate depth-adjustment mechanism.

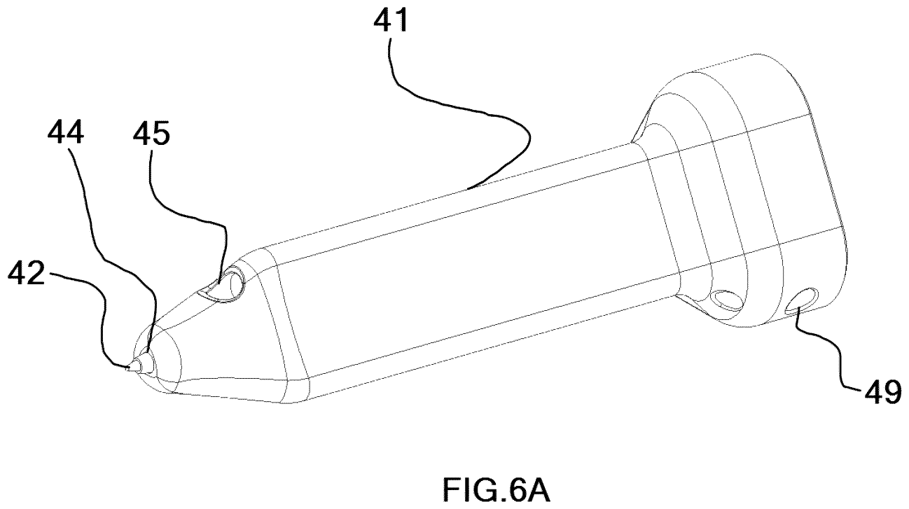

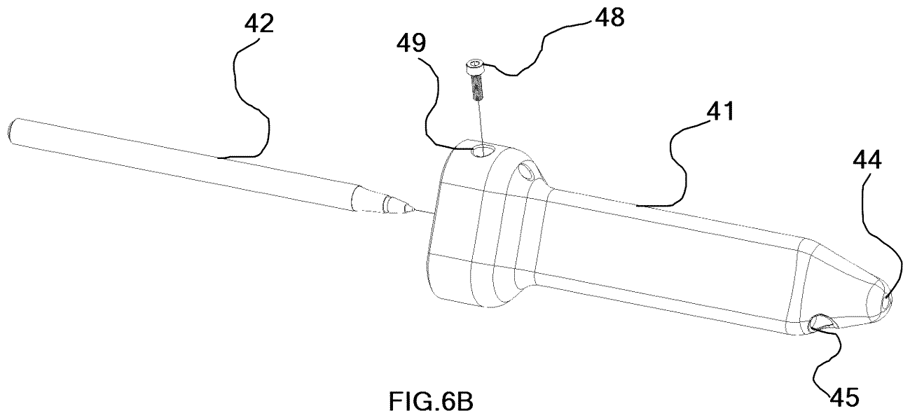

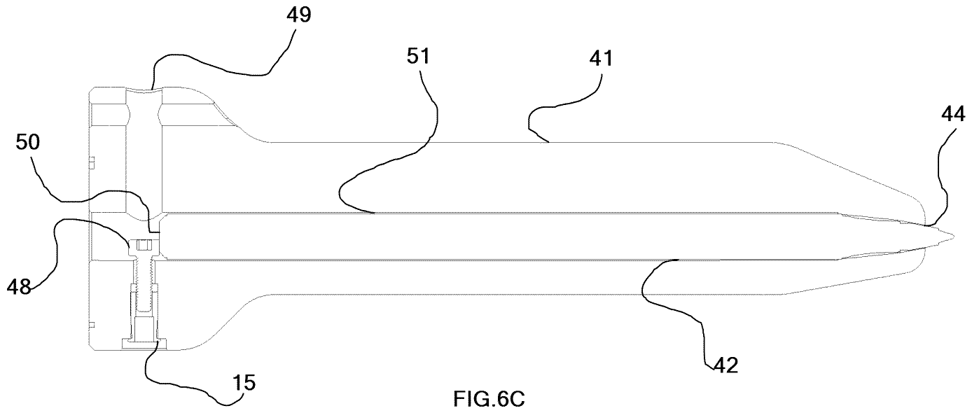

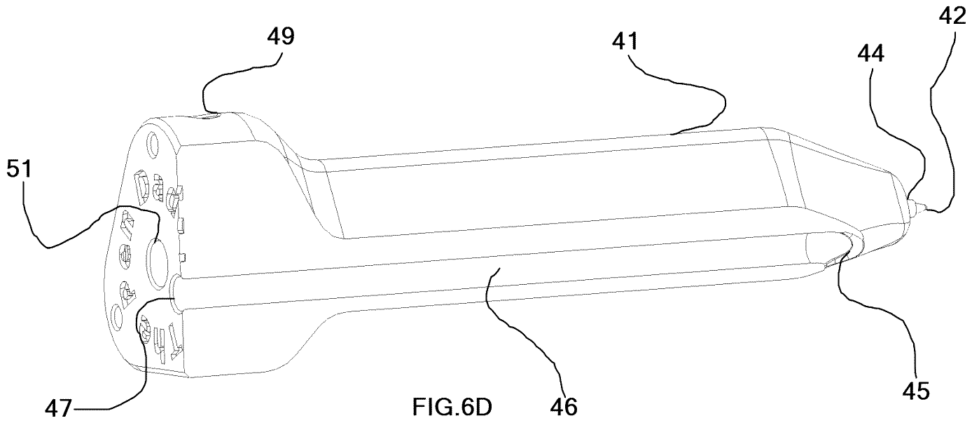

With reference to FIGS. 6A through 6D, and according to an embodiment of the present disclosure, a tamper-resistant pen protector is shown configured to house and secure a standard writing instrument such as a ballpoint pen or marker. The protector is particularly useful in environments where individuals may be at risk of harming themselves or others using exposed pen components-such as mental health facilities, correctional institutions, schools, and therapeutic settings.

The system includes a pen housing body (32) configured to receive a standard pen (33), and a tool-operated locking fastener (34). The pen is inserted tip-first into the housing through an insertion opening (35), and the fastener is inserted and tightened to physically block removal of the pen. In this configuration, the distal end of the fastener itself retains the pen in position, preventing withdrawal unless the fastener is first removed with a tool. This creates a highly secure, tamper-resistant system.

A tip opening (36) is provided at the front of the housing, allowing the pen tip to protrude for writing use. The rest of the pen remains enclosed, which reduces the risk of disassembly, breakage, or weaponization.

To ensure airflow in the event that the housing is accidentally or intentionally inserted into the user's mouth, the protector also includes one or more respiratory ports (37). These ports are formed as longitudinal air channels that extend along the body of the enclosure. As shown in FIG. 6D, the ports are continuous from one end to the other, enabling air to pass through the entire length of the housing. This feature provides a critical anti-suffocation safeguard in scenarios where the device could obstruct breathing.

FIG. 6A shows an isometric view of the pen protector in assembled form, with the pen fully enclosed except for its tip, FIG. 6B is an exploded isometric view showing the insertion of the pen and: fastener, FIG. 6C is a side cross-sectional view illustrating the fastener engaging the pen to secure it in place, FIG. 6D is a top cross-sectional view showing the longitudinal respiratory port running through the housing wall to enable airflow in emergency situations.

The housing may be constructed of high-strength polymer or other durable materials, and the fastener may be removable only with a proprietary or tamper-resistant tool. The shape, wall thickness, and materials can be varied according to application, and the protector may optionally include external ergonomic features such as grip texture or anchoring points.

This embodiment provides a secure, breathable, and durable housing for writing instruments, reducing risk in high-sensitivity environments while maintaining normal writing functionality for authorized users.

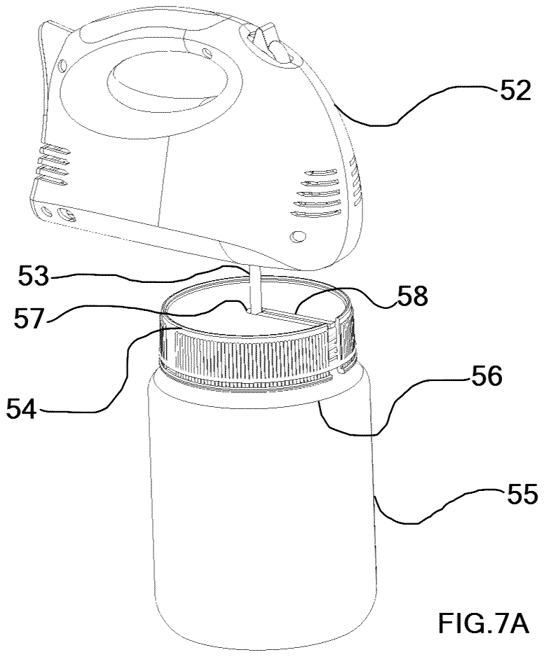

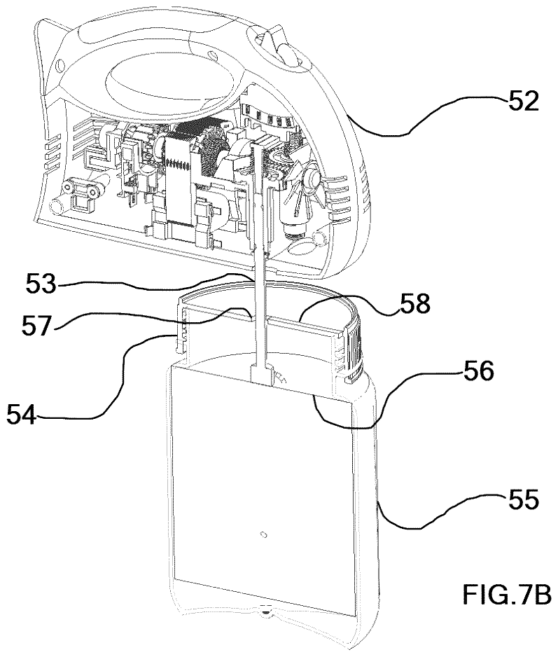

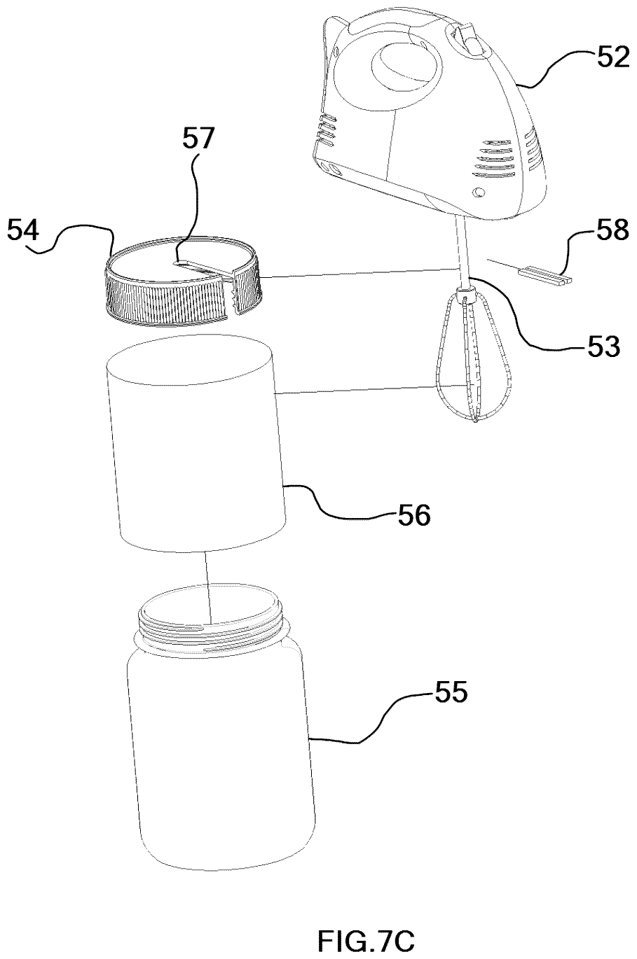

With reference to FIGS. 7A through 7C and according to an embodiment of the present disclosure, a container lid assembly is provided, designed to facilitate mess-free reintegration of separated substances within jars or similar containers, particularly those containing food products with distinct phases such as oils and solids. The lid is intended for use with a powered mixing implement such as a hand mixer, whisk, or immersion blender.

The system comprises a container lid (38) shaped and sized to engage the open mouth of a standard jar or food storage vessel (39). The lid may include threads, a press-fit rim, or other adaptable sealing interface around the perimeter, allowing it to fit a variety of common container sizes. A mixing aperture (40) is formed through the central region of the lid to allow insertion of a mixing tool.

In the embodiment shown, the aperture is elongated and slot-shaped, which better accommodates the lateral motion of mixer beaters compared to a simple round hole. However, the aperture may take on other geometries to accommodate different mixing tools. FIG. 7A shows the lid seated on a container; FIG. 7B provides a cross-sectional view illustrating a mixer (41) inserted through the aperture and interacting with the substance (42) in the jar.

To prevent spatter during mixing, the system optionally includes a flexible spatter guard (43), positioned over or integrated with the lid's mixing aperture. As shown in FIG. 7C (exploded view), the spatter guard is preferably constructed from silicone or another elastomeric material and features self-closing slits or a deformable membrane. This allows the mixer to pass through while forming a dynamic seal around the shaft, limiting escape of material.

This disclosure introduces a novel approach to managing phase separation in food storage. The lid not only prevents splatter but also enables efficient recombination of separated phases (such as oil and solids in natural peanut butter) directly in the storage container, eliminating the need for transfer. Key features include: a flexible peripheral seal that can adapt to a variety of jar mouth diameters, a central adaptable seal that accommodates mixer shafts of varying diameters and shapes, and universal compatibility with most standard kitchen hand mixers. These combined features result in a highly versatile, clean, and user-friendly solution to food preparation challenges. The lid improves hygiene and efficiency in the kitchen while reducing mess, waste, and cleanup time.

As shown, FIG. 7A shows an isometric view of the mixing lid mounted on a jar, FIG. 7B is a cross-sectional view showing the mixer inserted into the substance through the lid, and FIG. 7C is an exploded isometric view showing the lid, container, and optional flexible spatter guard prior to assembly.

This embodiment is particularly suited to household or commercial kitchens where convenience, cleanliness, and functional versatility are critical. It enhances the user experience during food preparation, particularly for products prone to separation, and may also serve as a helpful tool for individuals with limited dexterity or strength, and is useful for mixing high-viscosity or layered contents (e.g., nut butters, sauces, or dressings) where conventional open-top stirring results in mess, loss of material, or user inconvenience. The lid design improves user control and reduces cleanup, while remaining compatible with a wide variety of common kitchen tools and containers.

Like the prior embodiments, this mixing lid prioritizes user safety, usability, and containment of contents during use, but applies the underlying principles to culinary tasks rather than remote or writing instrument management.

1. A housing assembly for protecting an electronic device, the housing assembly comprising:
a housing comprising a housing cavity to accommodate the electronic device;
a cover releasably secured to the housing to enclose the electronic device within the housing assembly;
at least one access window positioned on at least one of the housing and the cover to allow a user to access the electronic device enclosed within the housing assembly; and,
at least one securement fastener to releasably secure the cover to the housing.

2. The housing assembly of claim 1, further comprising a locating tag pocket positioned within one of a first interior surface of the housing and a second interior surface of the cover, the locating tag pocket adapted to receive a locating tag.

3. The housing assembly of claim 1, wherein the at least one securement fastener is at least one tool-operated securement fastener to prevent unintended disassembly of the cover from the housing.

4. The housing assembly of claim 1, wherein the at least one access window is at least one of:
a button access window to allow the user to access a primary user interface of the electronic device;
an IR access port to allow transmission of infrared signals;
a volume access window to access at least one volume button; and,
a headphone access window to allow a headphone to connect with the electronic device.

5. The housing assembly of claim 1, wherein one of the cover and the housing comprises an alignment lip, wherein one of the cover and the housing comprises a lip receptacle adapted to receive the alignment lip, and wherein the lip receptacle engages with the alignment lip to resist separation of the cover from the housing.

6. The housing assembly of claim 5, wherein the housing assembly comprises one securement fastener to releasably secure the housing to the cover, and wherein the one securement fastener, the alignment lip, and the lip receptacle together releasably secure the cover to the housing.

7. The housing assembly of claim 5, wherein the alignment lip and the lip receptacle are each dimensioned to form an interference fit to provide mechanical retention between the cover and the housing.

8. The housing assembly of claim 1, further comprising an outer sleeve, the outer sleeve comprising:
a central cavity to accommodate and protect the cover and the housing; and
at least one functional opening aligned with the at least one access window, allowing a user to access the electronic device enclosed within the housing assembly.

9. The housing assembly of claim 8, wherein the outer sleeve comprises an elastomeric body.

10. The housing assembly of claim 8, wherein the outer sleeve comprises a wall contouring the housing and the cover, wherein the wall is hollow to allow the outer sleeve to collapse and deform under impact.

11. The housing assembly of claim 10, wherein the wall comprises:
an inner structural wall adjacent to the housing and the cover;
an outer structural wall facing outside the housing assembly; and,
an air chamber positioned between the inner structural wall and the outer structural wall.

12. The housing assembly of claim 11, wherein the wall is 0.5 inches thick.

13. The housing assembly of claim 11, wherein the inner structural wall and the outer structural wall are each 1 mm thick.

14. The housing assembly of claim 8, wherein the outer sleeve comprises at least one molded lug, wherein the housing comprises at least one lug receptacle adapted to receive the at least one molded lug to releasably secure the outer sleeve to the housing.

15. The housing assembly of claim 8, wherein the at least one functional opening comprises at least one of:
a shock button access window to allow the user to access the primary user interface of the electronic device;
a shock IR port to allow transmission of infrared signals;
a shock volume port to access at least one volume button; and,
a shock headphone port to allow a headphone to connect with the electronic device.

16. The housing assembly of claim 4, further comprising a button cover flap extending over the button access window to hide a portion of the primary user interface of the electronic device.

17. The housing assembly of claim 16, wherein the button cover flap extends over at least one primary user interface button, the button cover flap and the at least one primary user interface button forming a gap therebetween to prevent external forces from actuating the at least one primary user interface button through the button cover flap.

18. The housing assembly of claim 1, the housing further comprising at least one sliding plate assembly to adjust at least one of a length and a width of the housing cavity, each of the at least one sliding plate assemblies comprising:
an adjustment plate positioned within the housing cavity and adjacent to one of a length and a width of the electronic device; and
an adjustment fastener comprising:
a first end accessible through an opening of the housing; and,
a second end secured to the adjustment plate;
and wherein the position of the adjustment plate within the housing cavity is adjusted by the user by engaging the first end of the adjustment fastener.

19. The housing assembly of claim 18, wherein the adjustment fastener is a tool operated adjustment fastener to prevent unintended adjustment of the at least one sliding plate assembly.

20. The housing assembly of claim 1, wherein the at least one fastener is adjustable to loosen the cover from the housing to accommodate a thickness of the electronic device.
